(19) United States
(12) Patent Application Publication
(10) Pub. No.: US 2010/0129734 A1
(43) Pub. Date: May 27, 2010

(54) Polypropylene Providing Improved Surface Properties

(75) Inventor: Mark Miller, Houston, TX (US)

Correspondence Address: FINA TECHNOLOGY INC, PO BOX 674412, HOUSTON, TX, 77267-4412, US

(73) Assignee: Fina Technology, Inc., Houston, TX (US)

(21) Appl. No.: 12/619,937

(22) Filed: Nov. 17, 2009

Related U.S. Application Data
(60) Provisional application No. 61/117,498, filed on Nov. 24, 2008.

(51) Int. Cl. G03F 7/00; B32B 3/10; B32B 3/00; B05D 1/36

(52) U.S. Cl. 430/2; 428/195.1; 428/172; 427/258

(57) ABSTRACT

Propylene based films and methods of forming the sate are described herein. The propylene based films generally include a core layer formed of an olefin polymer, an embossing layer disposed on an exterior surface of the core layer and entirely formed of a metallocene formed propylene based polymer selected from propylene homopolymers, propylene based random copolymers formed of of polypropylene and polyethylene and combinations thereof, wherein the embossing layer includes an outer surface having a marking formed thereon and wherein the film is capable of retaining the marking thereon.

### CROSS-REFERENCE TO RELATED APPLICATIONS

This application claims the benefit of U.S. Provisional Patent Application Ser. No. 61/117,498, filed Nov. 24, 2008.

### FIELD

Embodiments of the present invention generally relate to polyolefin films. More particularly, embodiments of the present invention relate to metallocene catalyzed polypropylene films having novel surface properties that improve receptiveness of markings formed thereon.

### BACKGROUND

As reflected in the patent literature, propylene based polymers are frequently utilized in a variety of polymer applications, such as film formation. Frequently, it is desirable to provide markings, such as identifiable indicia, on the surface of the polypropylene based films. However, marking the polypropylene based film surface generally requires pretreatment to render the film receptive to marking. Such treatment may include heat treatment, such as corona discharge treatment, flame or plasma ionization, for example.

Therefore, a need exists to provide a polyolefin film, particularly, a polypropylene having an improved surface energy sufficient to accept and maintain markings.

### SUMMARY

Embodiments of the present invention include propylene based films. The propylene based films generally include a core layer formed of an olefin polymer, an embossing layer disposed on an exterior surface of the core layer and entirely formed of a metallocene formed propylene based polymer selected from propylene homopolymers, propylene based random copolymers formed of of polypropylene and polyethylene and combinations thereof, wherein the embossing layer includes an outer surface having a marking formed thereon and wherein the film is capable of retaining the marking thereon.

Embodiments further include methods of forming the films. The methods generally include providing a core layer formed of an olefin polymer; disposing the on an exterior surface of the core layer to form the film and marking an outer surface of the embossing layer.

### DETAILED DESCRIPTION

### Introduction and Definitions

A detailed description will now be provided. Each of the appended claims defines a separate invention, which for infringement purposes is recognized as including equivalents to the various elements or limitations specified in the claims. Depending on the context, all references below to the “invention” may in some cases refer to certain specific embodiments only. In other cases it will be recognized that references to the “invention” will refer to subject matter recited in one or more, but not necessarily all, of the claims. Each of the inventions will now be described in greater detail below, including specific embodiments, versions and examples, but the inventions are not limited to these embodiments, versions or examples, which are included to enable a person having ordinary skill in the art to make and use the inventions when the information in this patent is combined with available information and technology.

Various terms as used herein are shown below. To the extent a term used in a claim is not defined below, it should be given the broadest definition persons in the pertinent art have given that term as reflected in printed publications and issued patents at the time of tiling. Further, unless otherwise specified, all compounds described herein may be substituted or unsubstituted and the listing of compounds includes derivatives thereof.

Further, various ranges and/or numerical limitations may be expressly stated below. It should be recognized that unless stated otherwise, it is intended that endpoints are to be interchangeable. Further, any ranges include iterative ranges of like magnitude falling within the expressly stated ranges or limitations.

Embodiments of the present invention include propylene based films having an outer surface exhibiting novel surface characteristics that impart improved receptiveness to markings formed thereon.

### Catalyst Systems

Catalyst systems useful for polymerizing olefin monomers include any suitable catalyst system. For example, the catalyst system may include chromium based catalyst systems, single site transition metal catalyst systems including metallocene catalyst systems, Ziegler-Natta catalyst systems or combinations thereof, for example. The catalysts may be activated for subsequent polymerization and may or may not he associated with a support material, for example. A brief discussion of such catalyst systems is included below, but is in no way intended to limit the scope of the invention to such catalysts.

Metallocene catalysts may be characterized generally as coordination compounds incorporating one or more cyclopentadienyl (Cp) groups (which may be substituted or unsubstituted, each substitution being the same or different) coordinated with a transition metal.

The substituent groups on Cp may be linear, branched or cyclic hydrocarbyl radicals, for example. The inclusion of cyclic hydrocarbyl radicals may transform the Cp into other contiguous ring structures, such as indenyl, azulenyl and fluorenyl groups, for example. These contiguous ring structures may also he substituted or unsubstituted by hydrocarbyl radicals, such as C₁ to C₂₀ hydrocarbyl radicals, for example.

A specific, non-limiting, example of a metallocene catalyst is a bulky ligand metallocene compound generally represented by the formula:

[L]ₘM[A]ₙ;

wherein L is a bulky ligand, A is a leaving group, M is a transition metal and m and n are such that the total ligand valency corresponds to the transition metal valency. For example m may be from 1 to 4 and n may be from 0 to 3.

The metal atom “M” of the metallocene catalyst compound, as described throughout the specification and claims, may be selected from Groups 3 through 12 atoms and lanthanide Group atoms, or from Groups 3 through 10 atoms or from Sc, Ti, Zr, Hf, V, Nb, Ta, Mn, Re, Fe, Ru, Os, Co, Rh, Ir and Ni. The oxidation state of the metal atom “M” may range from 0 to +7 or is +1. +2, +3, +4 or +5, for example.

The bulky ligand generally includes a cyclopentadienyl group (Cp) or a derivative thereof. The Cp ligands) form at least one chemical bond with the metal atom M to form the “metallocene catalyst.” The Cp ligands are distinct from the leaving groups bound to the catalyst compound in that they are not as highly susceptible to substitution/abstraction reactions as the leaving groups.

Cp ligands may include ring(s) or ring system(s) including atoms selected from group 13 to 16 atoms, such as carbon, nitrogen, oxygen, silicon, sulfur, phosphorous, germanium, boron, aluminum and combinations thereof, wherein carbon makes up at least 50% of the ring members. Non-limiting examples of the ring or ring systems include cyclopentadienyl, cyclopentaphenanthrencyl, indenyl, benzindenyl, fluorenyl, tetrahydroindenyl, octahydrofluorenyl, cyclooctatetraenyl, cyclopentacyclododecene, 3,4-benzofluorenyl, 9-phenylfluorenyl, 8-H-cyclopent[a]acenaphthylenyl, 7-H-dibenzofluorenyl, indeno[1,2-9]anthrene, thiophenoindenyl, thiophenofluorenyl, hydrogenated versions thereof (e.g., 4,5,6,7-tetrahydroindenyl or “H₄Ind”), substituted versions thereof and heterocyclic versions thereof, for example.

Cp substituent groups may include hydrogen radicals, alkyls (e.g., methyl, ethyl, propyl, butyl, pentyl, hexyl, fluoromethyl, fluoroethyl, difluoroethyl, iodopropyl, bromohexyl, benzyl, phenyl, methylphenyl, tert-butylphenyl, chlorobenzyl, dimethylphosphine and methylphenylphosphine), alkenyls (e.g., 3-butenyl, 2-propenyl and 5-hexenyl), alkynyls, cycloalkyls (e.g., cyclopentyl and cyclohexyl), aryls, alkoxys methoxy, ethoxy, propoxy and phenoxy), aryloxys, alkylthiols, dialkylamines (e g., dimethylamine and diphenylamine), alkylamidos, alkoxycarbonyls, aryloxycarbonyls, carbamoyls, alkyl- and dialkyl-carbamoyls, aryloxys, acylaminos, aroylaminos, organometalloid radicals (e.g., dimethylboron), Group 15 and Group 16 radicals (e.g., methylsulfide and ethylsulfide) and combinations thereof, for example. In one embodiment, at least two substituent groups, two adjacent substituent groups in one embodiment, are joined to form a ring structure.

Each leaving group “A” is independently selected and may include any ionic leaving group, such as halogens (e.g., chloride and fluoride), hydrides, C₁ to C₁₂ alkyls (e.g., methyl, ethyl, propyl, cyclobutyl, cyclohexyl, heptyl, tolyl and trifluoromethyl), C₁ to C₁₂ alkyls (e.g., phenyl, methylphenyl, dimethylphenyl and trimethylphenyl), C₂ to C₁₂ alkenyls (e.g., C₂ to C₆ fluoroalkenyls), C₆ to C₁₂ aryls (e.g., C₇ to C₂₀ alkylaryls), C₁ to C₁₂ alkoxys (e.g., phenoxy, methyoxy, ethyoxy and propoxy), C₆ to C₁₆ aryloxys (e.g., benzoxy), C₇ to C₁₈ alkylaryloxys and C₁ to C₁₂ heteroatom-containing hydrocarbons and substituted derivatives thereof, for example.

Other non-limiting examples of leaving groups include amines, phosphines, ethers, carboxylates (e.g., C₁ to C₆ alkylcarboxylates, C₆ to C₁₂ arylcarboxylates and C₇ to C₁₈ alkylarylcarboxylates), dienes, alkenes, hydrocarbon radicals having from 1 to 20 carbon atoms (e.g., pentafluorophenyl) and combinations thereof, for example. In one embodiment, two or more leaving groups form a part of a fused ring or ring system.

In a specific embodiment, L and A may be bridged to one another to form a bridged metallocene catalyst. A bridged metallocene catalyst, for example, may be described by the general formula:

XCp^{A}Cp^{B}MAₙ;

wherein X is a structural bridge, Cp^{A} and Cp^{B} each denote a cyclopentadienyl group or derivatives thereof, each being the same or different and which may be either substituted or unsubstituted, M is a transition metal and A is an alkyl, hydrocarbyl or halogen group and n is an integer between 0 and 4, and either 1 or 2 in a particular embodiment.

Non-limiting examples of bridging groups “X” include divalent hydrocarbon groups containing at least one Group 13 to 16 atom, such as, but not limited to, at least one of a carbon, oxygen, nitrogen, silicon, aluminum, boron, germanium, tin and combinations thereof; wherein the heteroatom may also be a C₁ to C₁₂ alkyl or aryl group substituted to satisfy a neutral valency. The bridging group may also contain substituent groups as defined above including halogen radicals and iron. More particular non-limiting examples of bridging group are represented by C₁ to C₆ alkylenes, substituted C₁ to C₆ alkylenes, oxygen, sulfur, R₂C═, R₂Si═, ——Si(R)₂Si(R₂)——. R₂Ge═ or RP═ (wherein “═” represents two chemical bonds), where R is independently selected from hydrides, hydrocarbyls, halocarbyls, hydrocarbyl-substituted organometalloids, halocarbyl-substituted organometalloids, disubstituted boron atoms, disubstituted Group 15 atoms, substituted Group 16 atoms and halogen radicals, for example. In one embodiment, the bridged metallocene catalyst component has two or more bridging groups.

Other non-limiting examples of bridging groups include methylene, ethylene, ethylidene, propylidene, isopropyl idene, diphenylmethylene, 1,2-dimethylethylene, 1,2-diphenylethylene, 1,1,2,2-tetramethylethylene, dimethylsilyl, diethylsilyl, methyl-ethylsilyl, trifluoromethylbutylsilyl, bis(trifluoromethy)silyl, di(n-butyl)silyl, di(n-propyl)silyl, di(i-propyl)silyl, dicyclohexylsilyl, diphenylsilyl, cyclohexylphenylsilyl, t-butylcyclohexylsilyl, di(t-butylphenyl)silyl, di(p-tolyl)silyl and the corresponding moieties, wherein the Si atom is replaced by a Ge or a C atom; dimethylsilyl, diethylsilyl, dimethylgermyl and/or diethylgermyl.

In another embodiment, the bridging group may also be cyclic and include 4 to 10 ring members or 5 to 7 ring members, for example. The ring members may be selected from the elements mentioned above and/or from one or more of boron, carbon, silicon, germanium. nitrogen and oxygen, for example. Non-limiting examples of ring structures which may be present as or part of the bridging moiety are cyclobutylidene, cyclopentylidene, cyclohexylidene, cycloheptylidene, cyclooctylidene, for example. The cyclic bridging groups may be saturated or unsaturated and/or carry one or more substituents and/or be fused to one or more other ring structures. The one or more Cp groups which the above cyclic bridging moieties may optionally be fused to may be saturated or unsaturated. Moreover, these ring structures may themselves be fused, such as, for example, in the case of a naphthyl group.

In one embodiment, the metallocene catalyst includes CpFlu Type catalysts (e.g., a metallocene catalyst wherein the ligand includes a Cp fluorenyl ligand structure) represented by the following formula:

X(CpR¹ₙR²ₘ)(FIR³ₚ);

wherein Cp is a cyclopentadienyl group or derivatives thereof, Fl is a fluorenyl group, X is a structural bridge between Cp and Fl, R¹ is an optional substituent on the Cp, n is 1 or 2, R² is an optional substituent on the Cp bound to a carbon immediately adjacent to the ipso carbon, to is 1 or 2 and each R³ is optional, may be the same or different and may be selected from C₁ to C₂₀ hydrocarbyls. In one embodiment, p is selected from 2 or 4. In one embodiment, at least one is substituted in either the 2 or 7 position on the fluorenyl group and at least one other R³ being substituted at an opposed 2 or 7 position on the fluorenyl group.

In yet another aspect, the metallocene catalyst includes bridged mono-ligand metallocene compounds (e.g., mono cyclopentadienyl catalyst components). In this embodiment, the metallocene catalyst is a bridged “half-sandwich” metallocene catalyst. In yet another aspect of the invention, the at least one metallocene catalyst component is an unbridged “half sandwich” metallocene. (See, U.S. Pat. No. 6,069,213, U.S. Pat. No. 5,026,798, U.S. Pat. No. 5,703,187, U.S. Pat. No. 5,747.406, U.S. Pat. No. 5,026.798 and U.S. Pat. No. 6,069.213, which are incorporated by reference herein.)

Non-limiting examples of metallocene catalyst components consistent with the description herein include, for example cyclopentadienylzirconiumAₙ; indenylzirconiumAₙ; (1-methylindenyl)zirconiumAₙ; (2-methylindenyl)zirconiumAₙ, (1-propylindenyl)zirconiumAₙ; (2-propylindenyl)zirconiumAₙ; (1-butylindenyl)zirconiumAₙ; (2-butylindenyl)zirconiumAₙ; methylcyclopentadienylzirconiumAₙ; tetrahydroindenylzirconiumAₙ; pentamethylcyclopentachenylzirconiumAₙ; cyclopentadienylzirconiumAₙ; pentamethylcyclopentadienyltitaniumAₙ; tetramethylcyclopentyltitaniumAₙ; (1,2,4-trimethylcyclopentadienyl)zirconiumAₙ; dimethylsilyl(1,2,3,4-tetramethylcyclopentadienyl)(cyclopentadienyl)zirconiumAₙ; dimethylsilyl(1,2,3,4-tetramethylcyclopentadienyl)(1,2,3-trimethylcyclopentadienyl)zirconiumAₙ; dimethylsilyl(1,2,3,4-tetramethylcyclopentadienyl)(1,2-dimethylcyclopentadienyl)zirconiumAₙ; dimethylsilyl(1,2,3,4-tetramethylcyclopentadienyl)(2-methylcyclopentadienyl)zirconiumAₙ; dimethylsilylcyclopentadienylindenylzirconiumAₙ; dimethylsilyl(2-methylindenyl)(fluorenyl)zirconiumAₙ; diphenylsilyl(1,2,3,4-tetramethylcyclopentadienyl)(3-propylcyclopentadienyl)zirconiumAₙ; dimethylsilyl (1,2,3,4-tetramethylcyclopentadienyl)(3-t-butylcyclopentadienyl)zirconiumAₙ; dimethylgermyl(1,2-dithethylcyclopentadienyl)(3-isopropylcyclopenadienyl)zirconiumAₙ; dimethylsilyl(1,2,3,4-taramethylcyclopentadienyl)(3-methylcyclopentadienyl)zirconiumAₙ; diphenylmethylidene(cyclopentadienyl)(9-fluorenyl)zirconiumAₙ; diphenylmethylidenecyclopentadienylindenylzirconiumAₙ; isopropylidenebiscyclopentadienylzirconiumAₙ; isopropylidene(cyclopentadienyl)(9-fluorenyl)zirconiumAₙ; isopropylidene(3-methylcyclopentadienyl)(9-fluorenyl)zirconiumAₙ; ethylenebis(9-fluorenyl)zirconiumAₙ; ethylenebis(1-indenyl)zirconiumAₙ; ethylenebis(1-indenyl)zirconiumAₙ; ethylenebis(2-methyl-1-indenyl)zirconiumAₙ; ethylenebis(2-methyl-4,5,6,7-tetrahydro-1-indenyl)zirconiumAₙ; ethylenebis(2-propyl-4,5,6,7-tetrahydro-1-indenyl)zirconiumAₙ; ethylenebis(2-isopropyl-4,5,6,7-tetrahydro-1-indenyl)zirconiumAₙ; ethylenebis(2-butyl-4,5,6,7-tetrahydro-1-indenyl)zirconiumAₙ; ethylenebis(2-isobutyl-4,5,6,7-tetrahydro-1-indenyl)zirconiumAₙ; dimethylsilyl(4,5,6,7-tetrahydro-1-indenyl)zirconiumAₙ; diphenyl(4,5,6,7-tetrahydro-1-indenyl)zirconiumAₙ; ethylenebis(4,5,6,7-tetrahydro-1-denyl)zirconiumAₙ; dimethylsilylbis(cyclopentadienyl)zirconiumAₙ; dimethylsilylbis(9-fluorenyl)zirconiumAₙ; dimethylsilylbis(1-indenyl)zirconiumAₙ; dimethylsilylbis(2-methylindenyl)zirconiumAₙ; dimethylsilylbis(2-propylindenyl)zirconiumAₙ; dimethylsilylbis(2-butylindenyl)zirconiumAₙ; diphenylsilylbis(2-methylindenyl)zirconiumAₙ; diphenylsilylbis(2-propylindenyl)zirconiumAₙ; diphenylsilylbis(2-butylindenyl)zirconiumAₙ; dimethylgermylbis(2-methylindenyl)zirconiumAₙ; dimethylsilylbistetrahydroindenylzirconiumAₙ; dimethylsilylbistetramethylcyclopentadienylzirconiumAₙ; dimethylsilyl(cyclopentadienyl)(9-fluorenyl)zirconiumAₙ; diphenylsilyl(cyclopentadienyl)(9-fluorenyl)zirconiumAₙ; diphenylsilylbisindenylzirconiumAₙ: cyclotrimethylenesilyhetramethylcyclopentadienylcyclopentadienylzirconiumAₙ; cyclotetramethylenesilyltetramethylcyclopentadienylcyclopentadienylzirconiumAₙ; cyclotrimethylenesilyl(tetramethylcyclopentadienyl)(2-methylindenyl)zirconiumAₙ; cyclotrimethylenesilyl(tetramethylcyclopentadienyl)(3-methylcyclopentadienyl)zirconiumAₙ: cyclotrimethylenesilylbis(2-methylindenyl)zirconiumAₙ; cyclotrimethylenesilyl(tetramethylcyclopentadienyl)(2,3,5-trimethylclopentadienyl)zirconiumAₙ; cyclotrimethylenesilylbis(tetramethylcyclopentadienyl)zirconiumAₙ; dimethylsilyl(tetramethylcyclopentadieneyl)(N-tertbutylamido)titaniumAₙ; biscyclopentadienylchromiumAₙ; biscyclopentadienylzirconiumAₙ; butylcyclopentadienyl)zirconiumAₙ; bis(n-dodecyclcyclopentadienyl)zirconiumAₙ; bisethylcyclopentadienylzirconiumAₙ; bisisobutylcyclopentadienylzirconiumAₙ; bisisopropylcyclopentadienylzirconiumAₙ; bismethylcyclopentadienylzirconiumAₙ; bisoctylcyclopentadienylzirconiumAₙ; bis(n-pentylcyclopentadienyl)zirconiumAₙ; propylcyclopentadienyl)zirconiumAₙ; bistrimethylsilylcyclopentadienylzirconiumAₙ; bis(1,3-bis(trimethylsily)cyclopentadieny)zirconiumAₙ; bis(-ethyl-2-methylcyclopentadienyl)zirconiumAₙ; bis(-ethyl-3-methylcyclopentadienyl)(zirconiumAₙ; bispentamethylcyclopentadienylzirconiumAₙ; bispentamethylcyclopentadienylzirconiumAₙ; bis(1-propyl-3-methylcyclopentadienyl)zirconiumAₙ; bis(1-n-butyl-3-methylcyclopentadienyl)zirconiumAₙ; bis(1-isobutyl-3-methylcyclopentadienyl)zirconiumAₙ; bis(1-propyl-3-butylcyclopentadienyl)zirconiumAₙ; bis(1,3-n-butylcyclopentadienyl)zirconiumAₙ; bis(4,7-dimethylindenyl)zirconiumAₙ; bisindenylzirconiumAₙ; bis(2-methylindenyl)zirconiumAₙ; cyclopentadienylindenylzirconiumAₙ; bis(n-propylcyclopentadienyl)hafniumAₙ; bis(n-butylcyclopentadicnyl)hafniumAₙ; bis(n-pentylcyclopentadienyl)hafniumAₙ; (n-propylcyclopentadienyl)(n-butylcyclopentadienyl)hafniumAₙ; bis[(2-trimethylsilylethyl)cyclopentadienyl]hafniumAₙ; bis(trimethylsilylcyclopentadienyl)hafniumAₙ; bis(2-n-propylindenyl)hafniumAₙ; bis(2-n-butylindenyl)hafniumAₙ; dimethylsilylbis(n-propyleyclopentadienyl)hafniumAₙ; dimethylsilylbis(n-butyleyelopentadicnyl)hafniumAₙ; bis(9-n-propyfluorenyl)hafniumAₙ; bis(9-n-butylfluorenyl)hafniumAₙ; (9-n-propylfluorenyl)(2-n-propylindenyl)hafniumAₙ; bis(1-n-propyl-2-methylcyclopentadienyl)hafniumAₙ; (n-propylcyclopentadienyl)(1-n-propyl-3-n-butylcyclopentadienyl)hafniumAₙ; dimethylsilyltetramethylcyclopentadienylcyclopropylamidotitaniumAₙ; dimethylsilyltetramethylcyclopentadienylcyclobutylamidotitaniumAₙ; dimethylsilyltetramethylcyclopentadienylcyclopentylamidotitaniumAₙ; dimethylsilyltetramethylcyclopentadienyleyelohexylamidotitaniumAₙ; dimethylsilyltetramethylcyclopentadienylcycloheptylamidotitaniumAₙ; dimethylsilyltetramethylcyclopentadienylcyclooctylamidotitaniumAₙ; dimethylsilyltetramethylcyclopentadienylcyclononylamidotitaniumAₙ; dimethylsilyltetramethylcyclopentadienylcyclodecylamidotitaniumAₙ; dimethylsilyltetramethylcyclopentadienylcycloundecylamidotitaniumAₙ; dimethylsilyltetramethylcyclopentadienylcyclododecylamidotitaniumAₙ; dimethylsilyltetramethylcyclopentadienyl(sec-butylamido)titaniumAₙ; dimethylsilyltetramethylcyclopentadienyl(n-octylamido)titaniumAₙ; dimethylsilyl(tetramethylcyclopentadienyl)(n-decylamido)titaniumAₙ; dimethylsilyl(tetramethylcyclopentadienyl)(n-octadecylamido)titaniumAₙ; dimethylsilylbis(cyclopentadienyl)zirconiumAₙ; dimethylsilylbis(tetramethylcyclopentadienyl)zirconiumAₙ; dimethylsilylbis(methylcyclopentadienyl)zirconiumAₙ; dimethylsilylbis(dimethylcyclopentadienyl)zirconiumAₙ; dimethylsilyl(2,4-dimethylcyclopentadienyl) (3′,5′-dimethylcyclopentadienyl)zirconiumAₙ; dimethylsilyl(2,3,5-trimethylcyclopentadienyl)(2′,4′,5′-dimethylcyclopentadienyl)zirconiumAₙ; dimethylsilylbis(t-butylcyclopentadienyl)zirconiumAₙ; dimethylsilylbis(trimethylsilylyclopentadienyl)zirconiumAₙ; dimethylsilylbis(2-trimethylsilyl-4-t-butylcyclopentadienyl)zirconiumAₙ; dimethylsilylbis(4,5,6,7-tetrahydro-indenyl)zirconiumAₙ; dimethylsilylbis(indenyl)zirconiumAₙ; dimethylsilylbis(2-methylindenyl)zirconiumAₙ; dimethylsilylbis(2,4-dimethylindenyl)zirconiumAₙ; dimethylsilylbis(2,4,7-trimethylindenyl)zirconiumAₙ; dimethylsilylbis(2-methyl-4-phenyl(indenyl)zirconiumAₙ; dimethylsilylbis(2-ethyl-4-phenylindenyl)zirconiumAₙ; dimethylsilylbis(benz[f]indenyl)zirconiumAₙ; dimethylsilylbis(2-methylbenz[f]indenyl)zirconiumAₙ; dimethylsilylbis(benz[f]indenyl)zirconiumAₙ: dimethylsilylbis(2-methylbenz[f] indenyl)zirconiumAₙ; dimethylsilybis(3-methylbenz[f]indenyl)zirconiumAₙ; dimethylsilylbis(cyclopenta[cd]indenyl)zirconiumAₙ; dimethylsilylbis(cyclopentadienyl)zirconiumAₙ; dimethylsilylbis(tetramethylcyclopentadienyl)zirconiumAₙ; dimethylsilylbis(methylcyclopentadienyl)zirconiumAₙ; dimethylsilylbis(dimethylcyclopentadienyl)zirconiumAₙ; isopropylidene(cyclopentadienyl-fluorenyl)zirconiumAₙ; isopropylidene(cyclopentadienyl-indenyl)zirconiumAₙ: isopropylidene(cyclopentadienyl-2,7-di-t-butylfluorenyl)zireoniumAₙ; isopropylidene(cyclopentadienyl-3-methylfluorenyl)zirconiumAₙ; isopropylidene(cyclopentadienyl-4-methylfluorenyl)zirconiumAₙ; isopropylidene(cyclopentadienyl-octahydrofluorenyl)zirconiumAₙ; isopropylidene(methylcyclopentadienyl-fluorenyl)zirconiumAₙ; isopropylidene(dimethylcyclopentadienyl-fluorenyl)zirconiumAₙ; isopropylidene(tetramethylcyclopentadienyl-fluorenyl)zirconiumAₙ; diphenylmethylene(cyclopentadienyl-fluorenyl)zirconiumAₙ; diphenylmethylene(cyclopentadienyl-indenyl)zirconiumAₙ; diphenylmethylene(cyclopentadienyl-2,7-di-t-butylfluorenyl)zirconiumAₙ; diphenylmethylene(cyclopentadienyl-3-methylfluorenyl)zirconiumAₙ; diphenylmethylene(cyclopentadienyl-4-methylfluorenyl)zirconiumAₙ; diphenylmethylene(cyclopentadienyloctahydrofluorenyl)zirconiumAₙ; diphenylmethylene(methylcyclopentadienyl-fluorenyl)zirconiumAₙ; diphenylmethylene(dimethylcyclopentadienyl-fluorenyl)zirconiumAₙ; diphenylmethylene(tetramethylcyclopentadienyl-fluorenyl)zirconiumAₙ; cyclohexylidene(cyclopentadienyl-fluorenyl)zirconiumAₙ; cyclohexylidene(cyclopentadienylindenyl)zirconiumAₙ; cyclohexylidene(cyclopentadienyl-2,7-di-t-butylfluorenyl)zirconiumAₙ; cyclohexylidene(cyclopentadienyl-3-methylfluorenyl)zirconiumAₙ; cyclohexylidene(cyclopentadienyl-4-methylfluorenyl)zirconiumAₙ; cyclohexylidene(cyclopentadienyloetahydrofluorenyl)zirconiumAₙ; cyclohexylidene(methylcyclopentadienylfluorenyl)zirconiumAₙ; cyclohexylidene(dimethylcyclopentadienyl-fluorenyl)zirconiumAₙ; cyclohexylidene(tetramethylcyclopentadienylfluorenyl)zirconiumAₙ; dimethylsilyl(cyclopentadienyl-fluorenyl)zirconiumAₙ; dimethylsilyl(cyclopentadienyl-indenyl)zirconiumAₙ; dimethylsilyl(cyclopentdienyl-2,7-di-t-butylfluorenyl)zirconiumAₙ; dimethylsilyl(cyclopentadienyl-3-methylfluorenyl)zirconiumAₙ; dimethylsilyl(cyclopentadienyl-4-methylfluorenyl)zirconiumAₙ; dimethylsilyl(cyclopentadienyl-octahydrofluorenyl)zirconiumAₙ; dimethylsilyl(methylcyclopentanedienyl-fluorenyl)zirconiumAₙ; dimethylsilyldimethylcyclopentadienylfluorenyl)zirconiumAₙ: dimethylsilyl(tetramethylcyclopentadienyl-fluorenyl)zirconiumAₙ; isopropylidene(cyclopentadienyl-fluorenyl)zirconiumAₙ; isopropylidene(cyclopentadienyl-indenyl)zirconiumAₙ; isopropylidene(cyclopentadienyl-2,7-di-t-butylfluorenyl)zirconiumAₙ; cyclohexylidene(cyclopentadienylfluorenyl)zirconiumAₙ; cyclohexylidene(cyclopentadienyl-2,7-di-t-butylfluorenyl)zirconiumAₙ; dimethylsilyl(cyclopentadienylfluorenyl)zirconiumAₙ: methylphenylsilyltetramethylcyclopentadienyleyclopropylamidotitaniumAₙ; methylphenylsilyltetramethylcyclopentadienylcyclobutylamidotitaniumAₙ; methylphenylsilyltetramethylcyclopentadienylcyclopentylamidotitaniumAₙ; methylphenylsilyltetramethylcyclopentadienylcyclohexylamidotitaniumAₙ: methylphenylsilyltetramethylcyclopentadienylcycloheptylamidotitaniumAₙ; methylphenylsilyltetramethylcyclopentadienylcyclooctylamidotitaniumAₙ; methylphenylsilyltetramethylcyclopentadienylcyclononylamidotitaniumAₙ; methylphenylsilyltetramethyleyclopentadienylcyclodecylamidotitaniumAₙ; methylphenylsilyltetramethylcyclopentalienylcycloundecylamidotitaniumAₙ; methylphenylsilyltetramethylcyclopentadienyleyclododecylamidotitaniumAₙ; methylphenylsilyl(tetramethylcyclopentadienyl)(sec-butylamido)titaniumAₙ; methylphenylsilyl(tetramethylcyclopentadienyl)(n-octylamido)titaniumAₙ; methylphenylsilyl(tetramethylcyclopentadienyl)(n-decylamido)titaniumAₙ; methylphenylsilyl(tetramethylcyclopentadienyl)(n-octadecylamido)titaniumAₙ; diphenylsilyltetramethylcyclopentadienylcyclopropylamidotitaniumAₙ; diphenylsilyltetramethylcyclopentadienylcyclobutylamidotitaniumAₙ; diphenylsilyltetramethyleyclopentadienylcyclopentylamidotitaniumAₙ; diphenylsilyltetramethylcyclopentadienylcyclohexylamidotitaniumAₙ; diphenylsilyltetramethyleyclopentadienyleycloheptylamidotitaniumAₙ; diphenylsilyltetramethylcyclopentadienyleyelooctylamidotitaniumAₙ: diphenylsilyltetratnethylcyclopentadienylcyclononylamidotitaniumAₙ; diphenylsilyltetramethylcyclopentadienylcyclodecylamidotitaniumAₙ; diphenylsilyltetramethylcyclopentadienylcycloundceylamidotitaniumAₙ; diphenylsilyltetramethylcyclopentadienylcyclododecylamidotitaniumAₙ; diphenylsilyl(tetramethylcyclopentadienyl)(sec-butylamido)titaniumAₙ; diphenylsilyl(tetramethylcyclopentadienyl)(n-octylamido)titaniumAₙ; diphenylsilyl(tetramethylcyclopentadienyl)(n-decylamido)titaniumAₙ; and diphenylsilyl(tetramethylcyclopentadienyl)(n-octadecylamido)titaniumAₙ.

The metallocene catalysts may be activated with a metallocene activator for subsequent polymerization. As used herein, the term “metallocene activator” is defined to be any compound or combination of compounds, supported or unsupported, which may activate a single-site catalyst compound (e.g., metallocenes, Group 15 containing catalysts, etc.) This may involve the abstraction of at least one leaving group (A group in the formulas/structures above, for example) from the metal center of the catalyst component. The metallocene catalysts are thus activated towards olefin polymerization using such activators.

Embodiments of such activators include Lewis acids, such as cyclic or oligomeric polyhydrocarbylaluminum oxides, non-coordinating ionic activators (NCA), ionizing activators, stoichiometric activators, combinations thereof or any other compound that may convert a neutral metallocene catalyst component to a metallocene cation that is active with respect to olefin polymerization.

The Lewis acids may include alumoxane (e.g., “MAO”), modified alumoxane (e.g., “TIBAO”) and alkylaluminum compounds, for example. Non-limiting examples of aluminum alkyl compounds may include trimethylaluminum, triethylaluminum, triisobutylaluminum, tri-n-hexylaluminum and tri-n-octylaluminum, for example.

Ionizing activators are well known in the art and are described by, for example, Eugene You-Xian Chen & Tobin Marks, Cocatalysts for Mend-Catalyzed Olefin Polymerization: Activators, Activation Processes, and Structure-Activity Relationships 100(4) CHEMICAL REVIEWS 1391-1434 (2000). Examples of neutral ionizing activators include Group 13 tri-substituted compounds, in particular, tri-substituted boron, thallium, aluminum, gallium and indium compounds and mixtures thereof (e.g., trisperfluorophenyl boron metalloid precursors), for example. The substituent groups may be independently selected from alkyls, alkenyls, halogen, substituted alkyls, aryls, arylhalides, alkoxy and halides, for example. In one embodiment, the three groups are independently selected from halogens, mono or multicyclic (including halosubstituted) aryls, alkyls, alkenyl compounds and mixtures thereof, for example. In another embodiment, the three groups are selected from C₁ to C₂₀ alkenyls, C₁ to C₂₀ alkyls. C₁ to C₂₀ alkoxys, C₃ to C₂₀ aryls and combinations thereof, for example. In yet another embodiment, the three groups are selected from the group highly halogenated C₁ to C₄ alkyls, highly halogenated phenyls, and highly halogenated naphthyls and mixtures thereof, for example. By “highly halogenated”, it is meant that at least 50% of the hydrogens are replaced by a halogen group selected from fluorine, chlorine and bromine.

Illustrative, not limiting examples of ionic ionizing activators include trialkyl-substituted ammonium salts triethylammoniumtetraphenylborate, tripropylammoniumtetraphenylborate, tri(n-butyl)ammoniumtetraphenylborate, trimethylammoniumtetra(p-tolyl)borate, trimethylammoniumtetra(o-tolyl)borate, tributylammoniumtetra(pentafluorophenyl)borate, tripropylammoniumtetra(o,p-dimethylphenyl)borate, tributylammoniumtetra(m,m-dimethylphenyl)horate, tributylammoniumtetra(p-tri-fluoromethylphenyl)borate, tributylammoniumtetra(pentafluorophenyl)borate and tri(n-butyl)ammoniumtetra(o-tolyl)borate), N,N-dialkylanilinium salts (e.g., N,N-dimethylaniliniumtetraphenylborate, N,N-diethylaniliniumtetraphenylborate and N,N-2,4,6-pentamethylaniliumtetraphenylborate), dialkyl ammonium salts (e.g., disopropylammoniumtetrapentafluorophenylborate and dicyclohexylammoniumtetraphenylborate), triaryl phosphonium salts (e.g., triphenylphosphoniumtetraphenylborate, trimethylphenylphosphoniumtetraphenylborate and tridimethylphenylphosphoniumtetraphenylborate) and their aluminum equivalents, for example.

In yet another embodiment, an alkylaluminum compound may be used in conjunction with a heterocyclic compound. The ring of the heterocyclic compound may include at least one nitrogen, oxygen, and/or sulfur atom, and includes at least one nitrogen atom in one embodiment. The heterocyclic compound includes 4 or more ring members in one embodiment, and 5 or more ring members in another embodiment, for example.

The heterocyclic compound for use as an activator with an alkylaluminum compound may he unsubstituted or substituted with one or a combination of substituent groups. Examples of suitable substituents include halogens, alkyls, alkenyls or alkynyl radicals, cycloalkyl radicals, aryl radicals, aryl substituted alkyl radicals, acyl radicals, aroyl radicals, alkoxy radicals, aryloxy radicals, alkylthio radicals, dialkylamino radicals, alkoxycarbonyl radicals, aryloxycarbonyl radicals, carbamoyl radicals, alkyl- or dialkyl-carbamoyl radicals, acyloxy radicals, acylamino radicals, aroylamino radicals, straight, branched or cyclic, alkylene radicals or any combination thereof, for example.

Non-limiting examples of hydrocarbon substituents include methyl, ethyl, propyl, butyl, pentyl, hexyl, cyclopentyl, cyclohexyl, benzyl, phenyl, fluoromethyl, fluoroethyl, difluoroethyl, iodopropyl, bromohexyl or chlorobenzyl, for example.

Nan limiting examples of heterocyclic compounds utilized include substituted and unsubstituted pyrroles, imidazoles, pyrazoles, pyrrolines, pyrrolidines, purines, carbazoles, indoles, phenyl indoles, 2,5-dimethylpyrroles, 3-pentafluorophenylpyrrole, 4,5,6,7-tetrafluoroindole or 3,4-difluoropyrroles, for example.

Combinations of activators are also contemplated by the invention, for example, alumoxanes and ionizing activators in combinations. Other activators include aluminum/boron complexes, perchlorates, periodates and iodates including their hydrates, lithium (2,2′-bisphenyl-ditrimethylsilicate)-4T-HF and silylium salts in combination with a non-coordinating compatible anion, for example. In addition to the compounds listed above, methods of activation, such as using radiation and electro-chemical oxidation are also contemplated as activating methods for the purposes of enhancing the activity and/or productivity of a single-site catalyst compound, for example. (See, U.S. Pat. No. 5,849,852, U.S. Pat. No. 5,859,653, U.S. Pat. No. 5,869,723 and WO 98132775.)

The catalyst may be activated in any manner known to one skilled in the art. For example, the catalyst and activator may he combined in molar ratios of activator to catalyst of from 1000:1 to 0.1:1, or from 500:1 to 1:1, or from about 100:1 to about 250:1, or from 150:1 to 1:1, or from 50:1 to 1:1, or from 10:1 to 0.5:1 or from 3:1 to 0.3:1, for example.

The activators may or may not be associated with or hound to a support, either in association with the catalyst (e.g., metallocene) or separate from the catalyst component, such as described by Gregory G. Hlatky, Heterogeneous Single-Site Catalysts for Olefin Polymerization 100(4) CHEMICAL REVIEWS 1347-1374 (2000).

Metallocene Catalysts may be supported or unsupported. Typical support materials may include talc, inorganic oxides, clays and clay minerals, ion-exchanged layered compounds, diatomaceous earth compounds, zeolites or a resinous support material, such as a polyolefin, for example.

Specific inorganic oxides include silica, alumina, magnesia, titania and zirconia, for example. The inorganic oxides used as support materials may have an average particle size of from 5 microns to 600 microns or from 10 microns to 100 microns, a surface area of from 50 m²/g, to 1,000 m²/g or from 100 m²/g to 400 m²/g and a pore volume of from 0.5 cc/g to 3.5 cc/g or from 0.5 cc/g to 2.5 cc/g, for example.

Methods bar supporting metallocene catalysts are generally known in the art. (See, U.S. Pat. No. 5,643,847, which is incorporated by reference herein.)

Optionally, the support material, the catalyst component, the catalyst system or combinations thereof, may be contacted with one or more scavenging compounds prior to or during polymerization. The term “scavenging compounds” is meant to include those compounds effective for removing impurities (e.g., polar impurities) from the subsequent polymerization reaction environment. Impurities may be inadvertently introduced with any of the polymerization reaction components, particularly with solvent, monomer and catalyst feed, and adversely affect catalyst activity and stability. Such impurities may result in decreasing, or even elimination, of catalytic activity, for example. The polar impurities or catalyst poisons may include water, oxygen and metal impurities, for example.

The scavenging compound may include an excess of the aluminum containing compounds described above, or may be additional known organometallic compounds, such as Group 13 organometallic compounds. For example, the scavenging compounds may include triethyl aluminum (TMA), triisobutyl aluminum (TIBAl), methylalumoxane (MAO), isobutyl aluminoxane and tri-n-octyl aluminum. In one specific embodiment, the scavenging compound is TIBAl.

In one embodiment, the amount of scavenging compound is minimized during polymerization to that amount effective to enhance activity and avoided altogether if the feeds and polymerization medium may be sufficiently free of impurities.

Polymerization Processes

As indicated elsewhere herein, catalyst systems are used to form polyolefin compositions. Once the catalyst system is prepared, as described above and/or as known to one skilled in the art, a variety of processes may be carried out using that composition. The equipment, process conditions, reactants, additives and other materials used in polymerization processes will vary in a given process depending on the desired composition and properties of the polymer being formed. Such processes may include solution phase, gas phase, slurry phase, bulk phase, high pressure processes or combinations thereof, for example. (See, U.S. Pat. No. 5,525,678; U.S. Pat. No. 6,420,580; U.S. Pat. No. 6,380,328; U.S. Pat. No. 6,359,072; U.S. Pat. No. 6,346,586; U.S. Pat. No. 6,340,730; U.S. Pat. No. 6,339,134; U.S. Pat. No. 6,300,436; U.S. Pat. No. 6,274,684; U.S. Pat. No. 6,271,323; U.S. Pat. No. 6,248,845; U.S. Pat. No. 6,245,868; U.S. Pat. No. 6,245,705; U.S. Pat. No. 6,242,545; U.S. Pat. No. 6.211,105; U.S. Pat. No. 6,207,606; U.S. Pat. No. 6,180,735 and U.S. Pat. No. 6,147,173, which are incorporated by reference herein.)

In certain embodiments, the processes described above generally include polymerizing one or more olefin monomers to form polymers. The olefin monomers may include C₂ to C₃₀ olefin monomers, or C₂ to C₁₂ olefin monomers (e.g., ethylene, propylene, butene, pentene, methylpentene, hexene, octene and decene), for example. The monomers may include olefinic unsaturated monomers, C₄ to C₁₈ diolefins, conjugated or nonconjugated dienes, polyenes, vinyl monomers and cyclic olefins, for example. Non-limiting examples of other monomers may include norbornene, norbornadiene, isobutylene, isoprene, vinylbenzocyclobutane, sytrene, alkyl substituted styrene, ethylidene norbornene, dicyclopentadiene and cyclopentene, for example. The formed polymer may include homopolymers, copolymers or terpolymers, for example.

Examples of solution processes are described in U.S. Pat. No. 4,271,060, U.S. Pat. No. 5,001,205, U.S. Pat. No. 5,236,998 and U.S. Pat. No. 5,589,555, which are incorporated by reference herein.

One example of a gas phase polymerization process includes a continuous cycle system, wherein a cycling gas stream (otherwise known as a recycle stream or fluidizing medium) is heated in a reactor by heat of polymerization. The heat is removed from the cycling gas stream in another part of the cycle by a cooling system external to the reactor. The cycling gas stream containing one or more monomers may be continuously cycled through a fluidized bed in the presence of a catalyst under reactive conditions. The cycling gas stream is generally withdrawn from the fluidized bed and recycled back into the reactor. Simultaneously, polymer product may be withdrawn from the reactor and fresh monomer may be added to replace the polymerized monomer. The reactor pressure in a gas phase process may vary from about 100 psig to about 500 psig, or from about 200 psig to about 400 psig or from about 250 psig to about 350 psig, for example. The reactor temperature in a gas phase process may vary from about 30° C. to about 120° C., or from about 60° C. to about 115° C., or from about 70° C. to about 110° C. or from about 70° C. to about 95° C., for example. (See, for example, U.S. Pat. No. 4,543,399; U.S. Pat. No. 4,588.790; U.S. Pat. No. 5,028,670; U.S. Pat. No. 5,317,036; U.S. Pat. No. 5,352,749; U.S. Pat. No. 5,405,922; U.S. Pat. No. 5,436,304; U.S. Pat. No. 5,456,471; U.S. Pat. No. 5,462,999; U.S. Pat. No. 5,616,661; U.S. Pat. No. 5,627,242; U.S. Pat. No. 5,665,818; U.S. Pat. No. 5,677,375 and U.S. Pat. No. 5,668,228, which are incorporated by reference herein.)

Slurry phase processes generally include forming a suspension of solid, particulate polymer in a liquid polymerization medium, to which monomers and optionally hydrogen, along with catalyst, are added. The suspension (which may include diluents) may be intermittently or continuously removed from the reactor where the volatile components can be separated from the polymer and recycled, optionally after a distillation, to the reactor. The liquefied diluent employed in the polymerization medium may include a C₃ to C₇ alkane (e.g., hexane or isobutane), for example. The medium employed is generally liquid under the conditions of polymerization and relatively inert. A bulk phase process is similar to that of a slurry process with the exception that the liquid medium is also the reactant (e.g., monomer) in a bulk phase process. However, a process may be a bulk process, a slurry process or a bulk slurry process, for example.

In a specific embodiment, a slurry process or a bulk process may be carried out continuously in one or more loop reactors. The catalyst, as slurry or as a dry free flowing powder, may be injected regularly to the reactor loop, which can itself be filled with circulating slurry of growing polymer particles in a diluent, for example. Optionally, hydrogen (or other chain terminating agents, for example) may be added to the process, such as for molecular weight control of the resultant polymer. The loop reactor may be maintained at a pressure of from about 27 bar to about 50 bar or from about 35 bar to about 45 bar and a temperature of from about 38′C to about 121° C., :for example. Reaction heat may be removed through the loop wall via any suitable method, such as via a double-jacketed pipe or heat exchanger, for example.

Alternatively, other types of polymerization processes may be used, such as stirred reactors in series, parallel or combinations thereof, for example. Upon removal from the reactor, the polymer may be passed to a polymer recovery system for further processing, such as addition of additives and/or extrusion, for example.

### Polymer Product

The polymers (and blends thereof) formed via the processes described herein may include, but are not limited to, linear low density polyethylene, elastomers, plastomers, high density polyethylenes, low density polyethylenes, medium density polyethylenes, polypropylene and polypropylene copolymers, for example.

Unless otherwise desitmated herein, all testing methods are the current methods at the time of filing.

In one or more embodiments, the polymers include propylene based polymers. As used herein, the term “propylene based” is used interchangeably with the terms “propylene polymer” or “polypropylene” and refers to a polymer having at least about 50 wt. %, or at least about 70 wt. %, or at least about 75 wt. %, at least about 80 wt. %, or at least about 85 wt. % or at least about 90 wt. % polypropylene relative to the total weight of polymer, for example.

The propylene based polymers may have a molecular weight distribution (Mₙ/M_{w}) of from about 1.0 to about 20, or from about 1.5 to about 15 or from about 2 to about 12, for example.

In one or more embodiments, the propylene based polymers have a narrow molecular weight distribution (M_{w}/Mₙ). As used herein, the term “narrow molecular weight distribution” refers to a polymer having a molecular weight distribution of from about 1.5 to about 8, or from about 2.0 to about 7.5 or from about 2.0 to about 6.0, for example.

In one embodiment, the propylene polymer has a microtacticity of from about 89% to about 99%, for example.

The propylene based polymers may have a melting point (Tₘ) (as measured by DSC) of at least about 100° C. or from about 100° C. to about 163° C. for example.

The propylene based polymers may include about 10 wt. % or less, or about 6 wt. % or less, or about 5 wt. % or less, or about 4 wt. % or less or from about 0.2 wt. % to about 2 wt.% of xylene soluble material (XS), for example (as measured by ASTM D5492-06).

The propylene based polymers may have a melt flow rate (MFR) (as measured by ASTM D-1238) of from about 0.01 dg/min to about 1000 dg/min., for example. In one or more embodiments, the propylene based polymers have a low melt flow rate (MFR). As used herein, the term low melt flow rate refers to a polymer having a MFR of less than about 10 dg/min., or less than about 6 dg/min., or less than about 2.6 dg/min., or from about 0.5 dg/min. to less than 10 dg/min. or from about 0.5 dg/min. to about 6 dg/min., for example.

In one or more embodiments, the propylene based polymers are formed from a metallocene catalyst system.

In one or more embodiments, the polymers include polypropylene homopolymers. Unless otherwise specified, the term “polypropylene homopolymer refers to propylene homopolymers or those polymers composed primarily of propylene and amounts of other comonomers, wherein the amount of comonomer is insufficient to change the crystalline nature of the propylene polymer significantly.

In one or more embodiments, the polymers include propylene based random copolymers. Unless otherwise specified, the term “propylene based random copolymer” refers to those copolymers composed primarily of propylene and an amount of at least one comonomer, wherein the polymer includes at least about 0.5 wt. %, or at least about 0.8 wt. %, or at least about 2 wt. %. or at least about 4 wt. %, or from about 0.5 wt. % to about 10 wt. % or from about 1 wt.° /to about 7 wt. % comonomer relative to the total weight of polymer, for example. The comonomers may be selected from C₂ to C₁₀ alkenes. For example, the comonomers may be selected from ethylene, propylene, 1-butene, 1-pentene, 1-hexene, 1-heptene, 1-octene, 1-nonene, 1-decene, 4-methyl-1-pentene and combinations thereof In one specific embodiment, the comonomer includes ethylene. Further, the term “random copolymer” refers to a copolymer formed of macromolecules in which the probability of finding a given monomeric unit at any given site in the chain is independent of the nature of the adjacent units.

The propylene based random copolymers may exhibit a melt flow rate of at least about 2 dg./10 min., or from about 5 dg./10 min. to about 30 dg./10 min. or from about 10 dg./10 min. to about 20 dg./10 min., for example.

### Product Application

The polymers and blends thereof are useful in applications known to one skilled in the art, such as forming operations (e.g., film, sheet, pipe and fiber extrusion and co-extrusion as well as blow molding, injection molding and rotary molding). Films include blown, oriented or cast films formed by extrusion or co-extrusion or by lamination useful as shrink film, cling film, stretch film, sealing films, oriented films, snack packaging, heavy duty bags, grocery sacks, baked and frozen food packaging, medical packaging, industrial liners, and membranes, for example, in food-contact and non-food contact application. Fibers include slit-films, monofilaments, melt spinning, solution spinning and melt blown fiber operations for use in woven or non-woven form to make sacks, bags, rope, twine, carpet backing, carpet yarns, filters, diaper fabrics, medical garments and geotextiles, for example. Extruded articles include medical tubing, wire and cable coatings, sheets, such as thermoformed sheets (including profiles and plastic corrugated cardboard), geomembranes and pond liners, for example. Molded articles include single and multi-layered constructions in the form of bottles, tanks, large hollow articles, rigid food containers and toys, for example.

Embodiments of the invention generally include utilizing the polymers to form films, such as cast films or oriented films, for example. The films can be formed by known processes and may be utilized in known processes, such as packaging and/or labeling, for example. In one or more embodiments, the films have a thickness of from about 60 gauge to about 250 gauge, or from about 70 gauge to about 200 gauge or from about 80 gauge to about 175 gauge, for example.

The films generally include a core layer. The core layer may be formed of a polyolefin, such as those described herein. The core layer may have a thickness of from about 40 gauge to about 200 gauge, or from about 60 gauge to about 120 gauge or from about 65 gauge to about 80 gauge, for example.

One or more embodiments include marking the films. Such markings can include printing, embossing, coloring, adhesives, holographic images, coatings and combinations thereof, for example. The coatings can include metal layers, for example. The metal layers may include alumina, gold, silver, copper and combinations thereof, for example.

The films are marked by adhering the marking to an outer surface of an embossing layer. An interior surface of the embossing layer is disposed on an exterior surface of the core layer. In one or more embodiments, the embossing layer may have a thickness of from about 2 gauge to about 10 gauge, or from about 2 gauge to about 8 gauge or from about 4 gauge to about 8 gauge, for example.

The embossing layer may be disposed on the core layer by methods known in the art, such as via extrusion coating or coextrusion, for example.

One or more of the film layers, including the core layer, the embossing layer or combinations thereof, may further include an additive. The additives may include coloring agents, phosphorescence producing agents, reflective agents or combinations thereof, for example.

Conventional propylene based polymers, such as Ziegler-Natta formed polypropylene, generally require treatment to increase the bond strength between the embossing layer and the core layer, such as heat treatment, prior to marking. For example, the film (and particularly the embossing layer) may he heat treated by corona discharge treatment, flame or plasma ionization, for example.

It has been observed that the treatment increases the surface energy of the embossing layer, enabling marking thereof. However, conventional polypropylene based surfaces are known to contain soluble materials that may cause the treatment to decay or deteriorate, thereby rendering the treated surface ineffective for retaining the markings for extended periods of time.

However, the embossing layer of the embodiments described herein is formed from the metallocene formed propylene based polymers described herein. In one or more embodiments, the embossing layer is formed entirely of the metallocene formed propylene based polymers. As used herein, the term “formed entirely” means that no other polymer is utilized in the embossing layer.

Embodiments of the invention unexpectedly result in an embossing layer that is capable of marking. In particular, the propylene based polymers described herein (including metallocene (brined propylene based random copolymers and polypropylene having the novel characteristics described herein, such as low xylene solubles content, low melt flow rate and/or narrow molecular weight distribution) unexpectedly result in the formation of a stable post treated surface that provides improved surface energy to accept marking thereon and, more importantly, prevent or substantially reduce the deterioration of the post treatment so that the quality of the marking is retained undiminished over an extended period of time.

While the foregoing is directed to embodiments of the present invention, other and further embodiments of the invention may be devised without departing from the basic scope thereof and the scope thereof is determined by the claims that follow

What is claimed is:

1. A propylene based film comprising:
a core layer formed of an olefin polymer;
an embossing layer disposed on an exterior surface of the core layer and entirely formed of a metallocene formed propylene based polymer selected from propylene homopolymers, propylene based random copolymers consisting essentially of polypropylene and polyethylene and combinations thereof, wherein the embossing layer comprises an outer surface having a marking formed thereon and wherein the film is capable of retaining the marking thereon.

2. The film of claim 1, wherein the embossing layer is formed of the propylene based random copolymer.

3. The film of claim 2, wherein the propylene based random copolymer comprises from about 1 wt. % to about 7 wt. %.

4. The film of claim 1, wherein the propylene based polymer exhibits a molecular weight distribution of from about 2 to about 6.

5. The film of claim 1, wherein the propylene based polymer comprises less than about 4 percent xylene solubles.

6. The film of claim 1, wherein the propylene based polymer comprises less than about 2 percent xylene solubles.

7. The film of claim 1, wherein the marking is selected from printing, embossing, coloring, adhesives, holographic images, coatings and combinations thereof.

8. The film of claim 7, wherein the coating comprises a metal layer.

9. A method of forming films comprising:
providing a core layer formed of an olefin polymer;
disposing an embossing layer, entirely formed of a metallocene formed propylene based polymer selected from propylene homopolymers, propylene based random copolymers consisting essentially of polypropylene and polyethylene and combinations thereof an exterior surface of the core layer to form the film; and
marking an outer surface of the embossing layer.

10. The method of claim 9 further comprising heat treating the embossing layer prior to marking the outer surface.

11. The method of claim 9 further comprising forming the film into an article selected from labels and packaging materials.

12. The method of claim 11, wherein the article retains the marking thereon.
